(19) United States
(12) Patent Application Publication
(10) Pub. No.: US 2026/0333885 A1
(43) Pub. Date: Oct. 22, 2026

(54) SOLAR CELL MODULE AND METHOD FOR PRODUCING A SOLAR CELL MODULE

(71) Applicant: Fraunhofer-Gesellschaft zur Förderung der angewandten Forschung e.V., München (DE)

(72) Inventors: Julian WEBER, Freiburg (DE); Daniel VON KUTZLEBEN, Freiburg (DE); Torsten RÖSSLER, Freiburg (DE)

(73) Assignee: Fraunhofer-Gesellschaft zur Förderung der angewandten Forschung e.V., München (DE)

(21) Appl. No.: 19/113,995

(22) PCT Filed: Aug. 18, 2023
(86) PCT No.: PCT/EP2023/072825

§ 371 Date: Mar. 21, 2025

(30) Foreign Application Priority Data
Sep. 23, 2022 (DE) 10 2022 124 476.8

(51) Int. Cl. H10F 19/90; H10F 19/70

(52) U.S. Cl. CPC H10F 19/904; H10F 19/70; H10F 19/908

(57) ABSTRACT

A solar cell module having a plurality of photovoltaic solar cells with electrically contactable backsides. The solar cells are arranged in a matrix shingle arrangement having multiple rows of solar cells each having multiple solar cells and in a spatially parallel arrangement. The rows of solar cells are in an overlapping arrangement in overlap regions such that the backsides of the solar cells in a row of solar cells partly cover front-sides of solar cells in an adjacent row and the solar cells are arranged such that at least one backside of a solar cell in a row of solar cells partly covers front-sides of at least two solar cells in an adjacent row. At least one row of solar cells has an electrically conductive cross-connector that covers at least 50% of and makes electrical contact with the backsides of each of at least the non-marginal solar cells in the row.

### CROSS-REFERENCE TO RELATED APPLICATIONS

This application is a 371 National Phase of International Application No. PCT/EP2023/072825, filed Aug. 18, 2023, which claims priority from German Patent Application No. 10 2022 124 476.8, filed Sep. 23, 2022, both of which are incorporated herein by reference as if fully set forth.

### TECHNICAL FIELD

The invention relates to a solar cell module and to a method of producing a solar cell module.

### BACKGROUND

Photovoltaic solar cells typically have metallic contacting structures on the frontside. Such contacting structures are not transparent to incident electromagnetic radiation and hence reduce the area available for absorption on the frontside.

It is therefore known that solar cell modules can be formed with a shingle arrangement. In a shingle arrangement, adjacent solar cells overlap, and so the backside of a solar cell in an overlap region covers the frontside of an adjacent solar cell. This means that the metallic contacting structure is on the frontside of a solar cell in the overlap region and hence beneath the adjacent solar cell, where the upper solar cell in the overlap region need not have a large-area metallic contacting structure on its frontside. Based on the area of the solar cell module, it is thus possible to achieve a greater proportion of solar cell area available for the absorption of light.

A particularly advantageous arrangement of the solar cells arises in a matrix shingle arrangement. In this case, several rows of solar cells each having several solar cells are in a spatially parallel arrangement and, in the overlap region, a solar cell covers the front-sides of at least two neighboring solar cells. In the matrix shingle arrangement, the solar cells are thus in an offset arrangement in a direction of extension transverse to the rows of solar cells.

In the overlap region, the rows of solar cells are electrically conductively connected in order to form an electrical series interconnection of the rows of solar cells.

In principle, solar cell modules require connection elements for electrical connection of the solar cell module to external electrical elements and/or further solar cell modules.

In addition, for typical solar cell module sizes, the provision of bypass diodes is necessary in order to avoid local overheating (hotspot) in the event of partial shading and resulting damage to the solar cell module.

### SUMMARY

It is therefore an object of the present invention to provide a solar cell module and a method of producing a solar cell module with solar cells in a matrix shingle arrangement, which enables a robust and inexpensive interconnection with external circuits and/or internal electrical elements, especially bypass diodes.

This object is achieved by a solar cell module having one or more of the features disclosed herein and to a method of producing a solar cell module having one or more of the features disclosed herein. Advantageous configurations can be found in the description and claims that follow.

The solar cell module of the invention is preferably produced by the method of the invention, especially by a preferred embodiment thereof. The method of the invention is preferably designed to produce a solar cell module of the invention, especially a preferred embodiment thereof.

The solar cell module of the invention has a plurality of photovoltaic solar cells with electrically contactable backsides. The solar cells are arranged in a matrix shingle arrangement having multiple rows of solar cells each having multiple solar cells and in a spatially parallel arrangement, wherein the solar cells are in an overlapping arrangement in overlap regions such that the backsides of the solar cells in a row of solar cells partly cover the front-sides of the solar cells in an adjacent row of solar cells and the solar cells are arranged such that at least one backside of a solar cell in a row of solar cells partly covers the front-sides of at least two solar cells in an adjacent row of solar cells. An electrically conductive connection of the overlapping solar cells is preferably formed in the overlap region. Preferably, an electrical series interconnection of the rows of solar cells is formed by means of the electrically conductive connection in the overlap region.

This arrangement thus corresponds to the matrix shingle arrangement described at the outset.

Preferably, at least every non-marginal solar cell of one, in particular every, non-terminal row of solar cells partly covers the front-sides of at least two solar cells of an adjacent row of solar cells with the backside. Depending on the design of the matrix arrangement, marginal solar cells of some rows of solar cells may have a smaller width, such that these marginal solar cells do not cover two solar cells, but rather only one solar cell in an adjacent row of solar cells.

What is essential is that at least one row of solar cells has an electrically conductive cross-connector that covers at least 50% of and makes electrical contact with the backsides of each of at least the non-marginal solar cells in the row of solar cells.

Accordingly, the object stated at the outset is achieved by a method of producing a solar cell module, having the following method steps:

Multiple solar cells are arranged in a matrix shingle arrangement, so as to form multiple rows of solar cells each having multiple solar cells and in a spatially parallel arrangement. The rows of solar cells are in an overlapping arrangement in overlap regions such that the backsides of the solar cells in a row of solar cells partly cover the frontside of the solar cells in an adjacent row of solar cells and the solar cells are arranged such that at least one backside of a solar cell in a row of solar cells partly covers the front-sides of at least two solar cells in an adjacent row of solar cells. In the overlap region, an electrically conductive connection of the overlapping solar cells is preferably formed.

What is essential is that, at least in one row of solar cells, there is disposed an electrically conductive cross-connector that covers at least 50% of and makes electrical contact with the backsides of each of at least the non-marginal solar cells in the row of solar cells.

According to the invention, a cross-connector is thus provided, which covers a large area of and makes electrically conductive contact with at least the backsides of a row of solar cells.

This creates various options for the mounting of connecting elements on solar cells, which are arranged in a matrix shingle arrangement.

Because of its large-area arrangement and the large-area contact with the backsides of the solar cells, the cross-connector offers a mechanically stable connection and hence a robust construction, and moreover, because of the large area covered by the cross-connector on the backside of the solar cell in the row of solar cells, low absolute electrical contact resistance can be achieved between the cross-connector and the backsides of the solar cells. Because of this inexpensive and robust design, the invention thus enables the mounting of connecting elements such as connections for external interconnection, connection sockets or electrical or electronic elements of the solar cell module, in particular of bypass diodes.

In order to improve mechanical stability and reduce electrical contact resistance between the solar cells and the cross-connector, it is advantageous that the cross-connector covers and makes electrical contact with the backsides at least of the non-marginal of the solar cells in the row of solar cells in each case to an extent of at least 60%, preferably to an extent of at least 70%, in particular to an extent of at least 80%. Accordingly, it is advantageous in the method of the invention that the cross-connector is designed to cover and make electrical contact with at least 60%, preferably at least 70%, especially at least 80%, of the backsides of each of at least the non-marginal solar cell in the row of solar cells.

The two marginal solar cells in the row of solar cells on which the electrically conductive cross-connector is disposed may be covered by the electrically conductive cross-connector in order to reduce the requirement for process accuracy and/or for material savings in the case of a lower degree of coverage as well. Advantageously, the two marginal solar cells in the row of solar cells are each covered by and electrically conductively connected to the electrically conductive cross-connector at least to an extent of 20%, preferably at least to an extent of 30%, in particular at least to an extent of 40%. In order to reduce contact resistance, it is advantageous that the two marginal solar cells in the row of solar cells are also each covered by the electrically conductive cross-connector to an extent of at least 50%, in particular to an extent of at least 60%, preferably to an extent of at least 70%, in particular to an extent of at least 80%. In particular, it is advantageous that the two marginal solar cells in the row of solar cells have the same degree of coverage by the electrically conductive cross-connector as the internal (non-marginal, disposed between the two marginal solar cells) solar cells in the row of solar cells.

The percentage degrees of coverage described above refer to the area percentage of the backside of the respective solar cell.

A particularly simple and inexpensive configuration arises in an advantageous embodiment in which the cross-connector takes the form of an electrically conductive adhesive tape. Accordingly, an electrically conductive adhesive tape is advantageously used as cross-connector in the method of the invention.

Such electrically conductive adhesive tapes (electrically conductive tapes or charge collection tapes) are commercially available. In addition, they have the advantage that forming of the mechanical and electrically conductive connection does not require heat treatment that could impair components of the solar cells.

In a further advantageous configuration, the cross-connector is in a mechanical and electrically conductive arrangement by means of a conductive adhesive on the solar cells. In particular, the cross-connector preferably takes the form of a metal foil. In the method of the invention, the cross-connector is accordingly preferably arranged by means of a conductive adhesive in a row of solar cells, where the cross-connector used is preferably a metal foil.

The use of a metal foil, in particular a pliable metal foil, has the advantage that it is possible to make use of commercially available metal foils that have very good conductivity.

Likewise commercially available are conductive adhesives (ECA—electrically conductive adhesives).

In the case of typical conductive adhesives, a heat treatment for curing the conductive adhesive is necessary or at least advantageous.

In the manufacture of a solar cell module, the solar cells are typically arranged between a carrier substrate and at least one pliable cover element, in particular an encapsulation film. Subsequently, a cohesive thermal join is made by means of lamination in order to join carrier substrate and film.

Bonding of the cross-connector by means of conductive adhesive on the row of solar cells has the advantage that curing of the conductive adhesive can be effected during lamination, such that no additional heat treatment step is necessary. Advantageously, in the method of the invention for producing a solar cell module, therefore, curing of the conductive adhesive takes place during lamination of the solar cell module. In particular, the solar cells are preferably arranged between a carrier substrate and a pliable cover film, wherein a cohesive join between carrier substrate and cover film is made during the lamination, and preferably a cohesive join between cross-connector and solar cells.

It is within the scope of the invention that the cross-connector takes the form of a metal foil, especially preferably of a metal foil of one of the following metals: copper, tinned copper, aluminum.

The metal foil preferably has a thickness in the range of 5 μm to 100 μm, further preferably 10 μm to 50 μm, especially preferably 25 μm to 35 μm.

It is also within the scope of the invention that the cross-connector has several layers, in particular a pliable carrier layer coated with a conductive metal layer.

The total thickness of the cross-connector in the form of adhesive tape and/or multilayer cross-connector is preferably in the range of 5 μm to 100 μm, further preferably in the range of 10 μm to 50 μm.

By the present invention, it is thus possible in a simple manner, even when the solar cells are arranged in a matrix shingle arrangement, for individual rows of the solar cell module to be electrically separately contacted or connected to other electrical or electronic elements, for example bypass diodes.

For this purpose, it is advantageous that the solar cell module has at least one electrically conductive longitudinal connector which is electrically conductively connected to the cross-connector of a row of solar cells. The longitudinal connector extends over further rows of solar cells. It is within the scope of the invention that the longitudinal connector extends over further cross-connectors of the solar cell module.

The longitudinal connector thus enables, in a simple manner, the interconnection of a row of solar cells having a cross-connector, in particular the electrically conductive connection of a row of solar cells to a connection socket of the solar cell module.

The longitudinal connector preferably takes the form of a metallic longitudinal connector, especially preferably made of copper, and preferably has a thickness in the range of 300 μm to 500 μm.

The longitudinal connector is advantageously electrically insulated by means of an electrically insulating layer with respect to the further rows of solar cells and/or further cross-connectors of the solar cell module. It is within the scope of the invention that the longitudinal connector is ensheathed with an electrically insulating layer. It is likewise within the scope of the invention that an electrically insulating layer is disposed solely between longitudinal connector and the elements to be insulated, in particular the further solar cells of the solar cell module and/or further cross-connectors.

In an alternative advantageous configuration, the longitudinal connector is electrically conductively connected to at least one electrical cross-connector. Advantageously, the cross-connector has higher flexibility than the longitudinal connector. It is therefore advantageous that the longitudinal connector is disposed between solar cells and cross-connector.

Advantageously, the longitudinal connector is electrically conductively connected to the solar cells in the region in which the cross-connector covers the longitudinal connector. In this way, an electrically conductive connection of the cross-connector with the solar cells in the row of solar cells, in the present case an indirect electrically conductive connection via the longitudinal connector, is also made in the region in which the longitudinal connector is disposed between solar cells and cross-connector.

It is known that solar cell modules have one or more connection sockets, in particular on a backside of the solar cell module. Connection sockets serve to protect connection elements and/or electrical or electronic components against outside influences.

It is therefore advantageous that the solar cell module has one connection socket on each of at least two rows of solar cells and the longitudinal connector extends between the connection sockets, and in particular electrically conductively connects electrical connections of the two connection sockets.

It is advantageous to dispose one or more bypass diodes in one or more connection sockets of the solar cell module.

As described above, the cross-connector provides a simple means of electrically interconnecting a bypass diode in a matrix shingle arrangement.

In an advantageous embodiment, the solar cell module therefore has at least one bypass diode, and the cross-connector is electrically conductively connected to the bypass diode of the solar cell module. In particular, it is advantageous that the solar cell module has at least two rows of solar cells each with a cross-connector and the bypass diode is electrically conductively connected to the two rows of solar cells electrically by means of the cross-connectors in a customary manner, in particular connected parallel to the rows of solar cells in a customary manner.

In order to form a visually homogeneous picture of a frontside of the solar cell module, it is advantageous that the cross-connector on the side facing the solar cells in the row of solar cells, at least in gaps between the solar cells, preferably over the whole area, has a color corresponding to the color of the front-sides of the solar cells. Typical solar cells have a blue or black color impression on the frontside. Preferably, the cross-connector, on the side facing the solar cells in the row of solar cells, at least in gaps between the solar cells, is therefore preferably blue or black over the whole area, preferably black.

In an advantageous embodiment, the solar cell module therefore has a plurality of cover strips disposed between the solar cells and the cross-connector in the regions in which the cross-connector extends over the gap between two adjacent solar cells in a row of solar cells. As a result, only the cover strip is visible from the frontside of the solar cell module, but not the cross-connector. The cover strips preferably have a color corresponding to the color of the front-sides of the solar cells, especially preferably a blue or black shade.

The cover strips are preferably of electrically insulating design.

The present invention has the advantage that further development of solar cell modules known per se with matrix shingle arrangement by additional provision of one or more cross-connectors is possible. In particular, it is within the scope of the invention to use previously known photovoltaic solar cells, in particular typically used subcells for forming the solar cell module.

In an advantageous further development of the solar cell module, at least for the rows of solar cells that are electrically conductively connected by means of a cross-connector, solar cells with a modified metallic backside contacting structure are used.

Advantageously, the solar cells at least of the row of solar cells on which the cross-connector is disposed each have a metallic backside contacting structure which extends beyond an overlap region on the backside of the solar cell such that a series interconnection subregion of the metallic backside contacting structure in the overlap region adjoins the frontside of an adjacent solar cell, and a cross-connection subregion of the metallic backside contacting structure is covered by and directly electrically conductively connected to the cross-connector.

It is known, in solar cells for shingle arrangement, that a striplike metallic backside contacting structure in the manner of a busbar can be formed on the backside on at least one side. With this metallic backside contacting structure, the solar cell overlaps such that the metallic backside contacting structure abuts a metallic front-side contacting structure of the adjacent solar cell in the overlap region to form an electrical series interconnection.

In the present further development, the metallic backside contacting structure has a cross-connection subregion in addition to the series interconnection subregion, which overlaps with the adjacent solar cell. In the cross-connection subregion, the solar cell does not overlap with the adjacent solar cell, such that the metallic backside contacting structure in the cross-connection subregion is accessible on the backside, such that the cross-connector can be disposed on and can be electrically conductively connected to the cross-connection subregion of the metallic backside contacting structure.

This results in the advantage that an electrically conductive connection with a very low contact resistance can be formed.

The metallic backside contacting structure is preferably formed to an extent of at least 50% from a metal from the group of silver and copper.

Typical previously known solar cells have a large-area, in particular full-area, aluminum layer on the backside, which is used on the backside for merging and discharging of the charge carriers. Aluminum is less costly than other metals, such as silver in particular, but has the disadvantage that contacts with lower mechanical stability and comparatively high contact resistance are formed by connection methods typically used, in particular soldering. Provision of what are called “solder pads” of a different metal is therefore known, in order to form a stable electrically conductive connection with low contact resistance.

The present invention has the advantage that, because of the large-area coverage of the backsides of the solar cells in the row of solar cells by the cross-connector, mechanically stable contacting with a low contact resistance is formed even directly on an aluminum backside of a solar cell. This is because, owing to the large area, advantageous mechanical stability and electrical quality of the contact is achieved. Electrical quality is further increased by the advantageous configuration of the above-described cross-connection subregions of the metallic backside contacting structure.

In an advantageous further development of the solar cell module of the invention, the solar cells at least of the row of solar cells on which the cross-connector is disposed are each formed on the backside with a backside contacting surface formed from aluminum, where the backside contacting surface covers preferably at least 60%, especially preferably 80%, of the backside of the solar cell, and preferably the aluminum backside contacting surface is formed over the whole area. The cross-connector is disposed on the backside contacting surfaces and is directly electrically conductively connected to the backside contacting surfaces formed from aluminum.

In order to form an efficient matrix shingle arrangement, it is advantageous that, in each row of solar cells of the solar cell module apart from a terminal row of solar cells, at least the non-marginal solar cells in the overlap region cover at least two solar cells of the adjacent row of solar cells.

Advantageously, the cross-connector is mechanically connected to the solar cells over at least 80% of the area, further preferably at least 90% of the area, especially preferably over 100% of the area, with which the cross-connector covers the backsides of solar cells in the row of solar cells. This ensures high mechanical stability.

In order to form low contact resistance, the cross-connector is advantageously electrically connected to the solar cells over at least 80% of the area, further preferably at least 90% of the area, especially preferably over 100% of the area, with which the cross-connector covers the backsides of solar cells in the row of solar cells.

In an advantageous configuration, the solar cell module has, at least at each of the two terminal rows of solar cells, an electrically conductive cross-connector which covers and makes electrical contact with at least 50% each of the backsides of at least the non-marginal solar cells of the row of solar cells. These two cross-connectors are used to interconnect the solar cell module with external circuits or other solar cell modules. In this configuration, that terminal row of solar cells which overlaps with the backside an adjacent row of solar cells is inactive, i.e. does not contribute to the conversion of electromagnetic radiation to electrical energy. This configuration features a visual uniform frontside and yet simple interconnection by the two cross-connectors on the terminal rows of solar cells.

The percentages for formation of the metallic contacting structures relate to percent by mass.

The solar cell module may include encapsulation elements known per se. In particular, it is within the scope of the invention that the solar cell module has at least one or more, preferably all, of the following layers, starting from a side facing the radiation in use:
frontside glass (PV front glass)
front encapsulation film (PV encapsulant foil), preferably composed of ethylene-vinyl acetate (EVA), polyolefin elastomers (POE)
solar cells of the solar cell module, preferably composed of silicon
in the region of the cross-connector: cross-connectors preferably composed of copper
rear encapsulation film (PV encapsulant foil), preferably composed of ethylene-vinyl acetate (EVA), polyolefin elastomers (POE)
backside cover (PV backsheet), preferably composed of polyethylene (PE), polyethylene terephthalate (PET)

### BRIEF DESCRIPTION OF THE DRAWINGS

Further advantageous features and configurations are elucidated hereinafter with reference to working examples and the figures. The figures show:

FIG. 1 a photovoltaic solar cell for a first working example of a solar cell module of the invention;

FIG. 2 a side view and

FIG. 3 a top view from behind of the first working example of a solar cell module of the invention;

FIG. 4 a top view from behind of a second working example and

FIG. 5 a top view from behind of a third working example of a solar cell module of the invention;

FIG. 6 a photovoltaic solar cell for a solar cell module according to FIG. 7;

FIG. 7 a fourth working example of a solar cell module of the invention, shown in top view from behind;

FIG. 8 a fifth working example of a solar cell module of the invention, shown in top view from behind, and

FIGS. 9 to 11 section images for FIG. 8, where the section plane is in each case perpendicular to the plane of the drawing in FIG. 8.

### DETAILED DESCRIPTION

All the figures show schematic diagrams that are not true to scale. Identical reference signs in the figures denote elements that are the same or have the same effect.

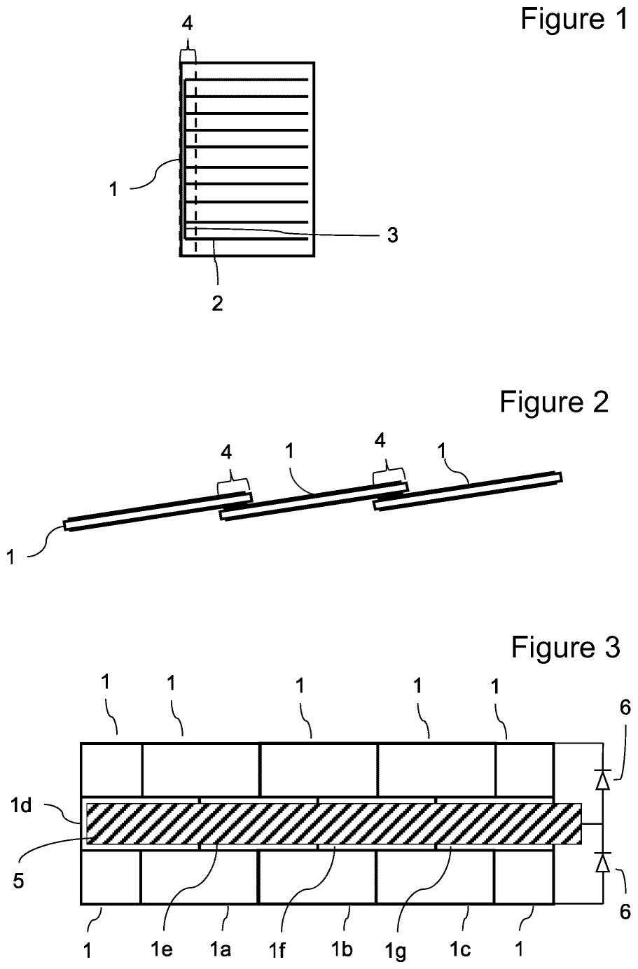

FIG. 1 shows a top view from the front of a schematic diagram of a photovoltaic solar cell 1 for a first working example of a solar cell module of the invention. The solar cell 1 has a metallic contacting structure on the frontside, in comb-like form in a known manner, with a plurality of parallel contact fingers 2 electrically conductively connected by a busbar 3 running perpendicular to the contact fingers 2.

The solar cell 1 is formed in a manner known per se as a photovoltaic solar cell based on a silicon wafer as semiconductor substrate and has an emitter on the frontside, with which contact is made by means of the contact fingers 2 and the busbar 3. On the backside of the solar cell is disposed an aluminum layer over the full area, in order to make electrical contact with the base of the solar cell. It is within the scope of the invention to use further developments of this solar cell structure or else other solar cell structures as solar cells for a solar cell module of the invention. In particular, it is within the scope of the invention to dispose additional layers for improving electrical quality on the frontside, in particular for reduction of the rate of recombination on the surface or the optical properties.

The solar cell shown in FIG. 1 represents a partial solar cell which was produced by splitting a larger silicon substrate on which several partial solar cells were formed. It is also within the scope of the invention to use solar cells produced entirely on an undivided silicon wafer.

In FIG. 1, dashed lines indicate an overlap region 4 in which, because of the shingle arrangement, the backside of an adjacent solar cell overlaps with the frontside of the solar cell shown in FIG. 1.

A schematic diagram of the first working example of a solar cell module of the invention is shown in side view in FIG. 2 and in top view from behind in FIG. 3:

The solar cell module according to the first working example has a plurality of photovoltaic solar cells 1 according to FIG. 1 with electrically contactable backsides, where the backsides are fully covered by an aluminum layer.

The solar cells 1 are arranged in a matrix shingle arrangement, which in the present case has a spatially parallel arrangement of three rows of solar cells, each with several solar cells.

In FIG. 3, it can be seen that the lowest and uppermost rows of the spatially parallel arrangement of rows of solar cells in the diagram according to FIG. 3 each have five solar cells, where the middle row of solar cells has four solar cells 1.

As can be seen in FIG. 2, the rows of solar cells are in an overlapping arrangement in overlap regions 4, such that the backsides of the solar cells 1 in a row of solar cells partly cover the front-sides of the solar cells 1 in an adjacent row of solar cells.

Furthermore, the solar cells are arranged such that at least one backside of a solar cell in a row of solar cells partly covers the front-sides of at least two solar cells in an adjacent row of solar cells. In the working example according to FIG. 3, for example, the solar cell la partly covers the solar cells 1d and le, the solar cell 1b partly covers the solar cells le and 1f, and the solar cell 1c partly covers the solar cells 1f and 1g.

In order to form this partial overlap, the marginal solar cells 1 of the lowermost and the uppermost rows of solar cells according to FIG. 3 are each formed only with half the width compared to the remaining solar cells 1 of the solar cell module.

What is essential is that the solar cell module has an electrically conductive cross-connector 5 that covers at least 50% of and makes electrical contact with the backsides of each solar cell 1 in the middle row of solar cells. In this working example, the row of solar cells contacted by the cross-connector has four solar cells 1. The two non-marginal solar cells le and If are covered by the cross-connector in the present case to an extent of about 80% (drawing not to scale), as is the right-hand marginal solar cell 1g according to FIG. 3, where the cross-connector 5 for contacting extends beyond the right edge of the solar cell 1. In the left-hand marginal solar cell 1d, the cross-connector is at a distance from the left-hand edge of the solar cell, and so the degree of coverage is somewhat lower.

The cross-connector 5 is designed as an electrically conductive adhesive tape and extends beyond the area of the solar cells according to FIG. 3 at the right-hand edge of the solar cell module, so as to enable, in a simple manner, lateral interconnection with further electronic elements, in particular a bypass diode of the solar cell module.

FIG. 3 schematically shows an interconnection diagram with two bypass diodes 6, where a bypass diode 6 is interconnected between a lower terminal of the solar cell module and the cross-connector 5 and a second bypass diode 6 between the cross-connector 5 and an upper terminal of the solar cell module.

In a modification of the first working example of a solar cell module of the invention, the cross-connector 5 takes the form of a copper foil having a thickness of 30 μm. Conductive adhesive is disposed between the cross-connector 5 and the solar cells 1 of the middle row of solar cells. In a later method step, in the manufacture of the solar cell module, lamination is effected in a manner known per se. For this purpose, a transparent carrier substrate (glass) of the solar cell module is disposed on the frontside, and a protective cover (backsheet) on the backside. A front encapsulation film (EVA) is arranged between carrier substrate and solar cells, and a rear encapsulation film (EVA) between solar cells and backsheet. By means of lamination, the foils are joined such that the solar cells 1 and the cross-connector 5 in particular are embedded between the foils. In this modification of the first working example, the conductive adhesive applied between cross-connector 5 and solar cells 1 of the middle row of solar cells is also cured during lamination.

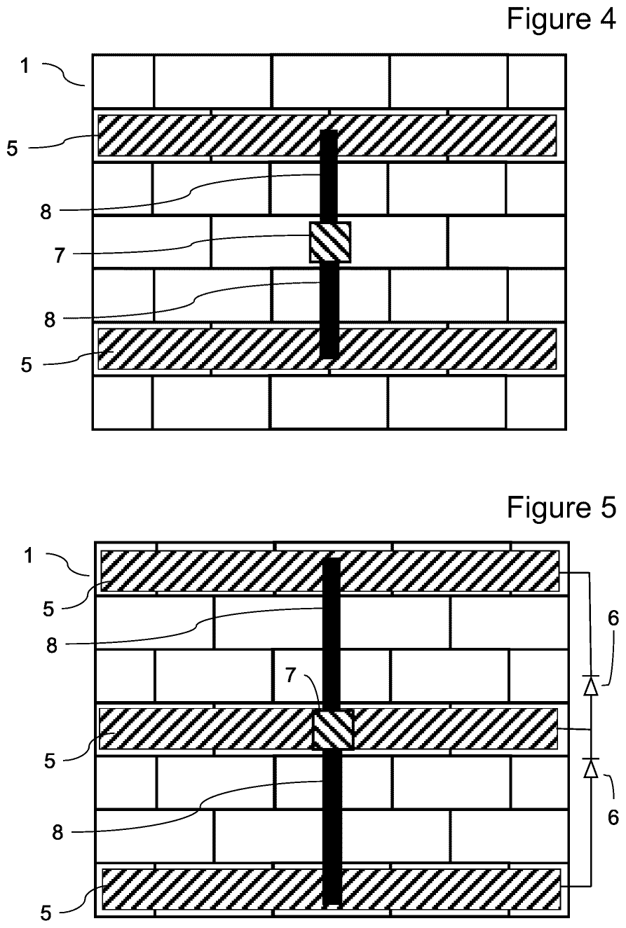

FIGS. 4 and 5 show two further working examples for a solar cell module of the invention. For avoidance of repetitions, only the substantial differences are discussed.

In the working examples shown in FIG. 4 and FIG. 5, the photovoltaic solar cell 1 shown in FIG. 1 is likewise used, arranged in matrix shingle arrangement. The working examples shown in FIGS. 4 and 5 each have a spatial parallel arrangement of 7 rows of solar cells, where, as in the first working example, the rows of solar cells alternately have five and four solar cells, where each of the marginal solar cells in the rows of solar cells with five solar cells has only half the width.

In the second working example shown in FIG. 4, a cross-connector 5 in the form of an electrically conductive adhesive tape is disposed in the second and sixth rows respectively. In this working example, the cross-connectors do not extend beyond the solar cell area. A connection socket 7 disposed centrally on the backside of the solar cell module contains a bypass diode.

By means of two longitudinal connectors 8 in the form of a copper strip, an electrical feed is formed from the two cross-connectors 5 to the connection socket 7. The bypass diode disposed in the connection socket 7 is electrically conductively connected to the longitudinal connectors 8, such that a bypass diode is intermediately connected between the two cross-connectors 5.

The third working example of a solar cell module of the invention, shown in FIG. 5 in rear view, has three cross-connectors 5. The cross-connectors 5 are arranged in the first, fourth and seventh rows of solar cells. The solar cell module likewise has a connection socket 7 and two longitudinal connectors 8 in the middle. In the connection socket 7 are disposed two bypass diodes 6, where a first bypass diode 6 is electrically conductively connected to the lower longitudinal connector 8 and the middle cross-connector 5, and a second bypass diode 6 to the middle cross-connector 5 and the upper longitudinal connector 8. A schematic diagram of the electrical circuit diagram achieved is shown for illustration at the left-hand edge of FIG. 5.

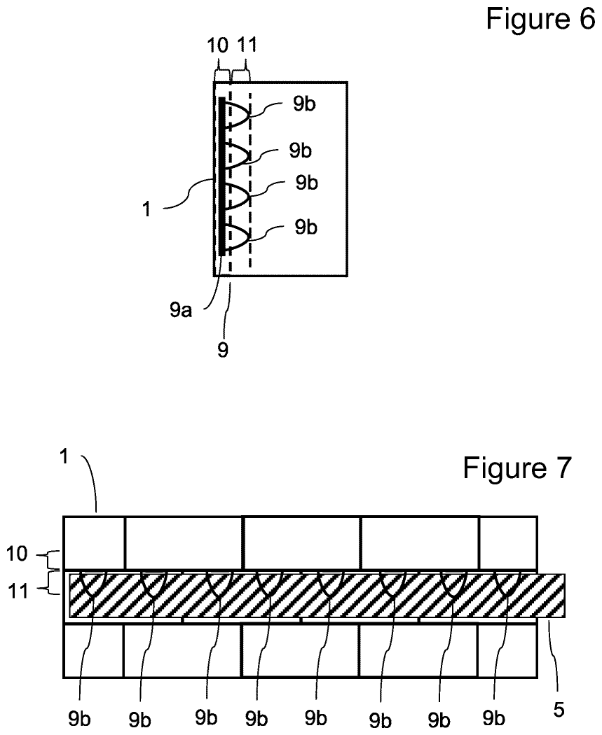

FIG. 6 shows a top view of the reverse side of a photovoltaic solar cell 1 for a fourth working example of a solar cell module of the invention.

The configuration of the frontside of the photovoltaic solar cell shown in FIG. 6 corresponds to the solar cell 1 shown in FIG. 1.

In contrast to the solar cell shown in FIG. 1, the solar cell shown in FIG. 6 on the backside has a metallic backside contacting structure 9 disposed on the aluminum layer with cross-connecting arcs, predominantly made of silver. The backside contacting structure 9 has a busbar 9a and the cross-connecting arcs 9b, which extend from the busbar 9a over the backside surface of the solar cell.

FIG. 6 indicates by dashed lines that, in the matrix shingle interconnection of the solar cell 1 according to FIG. 6, in a series interconnection subregion 10, the busbar 9a in particular is adjacent to the frontside of an adjacent solar cell 1, and a cross-connection subregion 11, which essentially comprises the cross-connection arcs 9b, is covered by a cross-connector 5 and is electrically conductively connected directly to this cross-connector 5.

FIG. 7 shows a backside view of the fifth working example. The fifth working example constitutes a further development of the third working example shown in FIGS. 1 to 3. The further development consists in the backside contacting structure 9 with busbar 9a and cross-connecting arcs 9b, described in FIG. 6. As shown in FIG. 7, only the solar cells 1 in the middle row of solar cells have the backside contacting structure 9. In the backside view, only the cross-connection arcs 9b are visible. For better representation, only two cross-connection arcs are shown for each full-width solar cell 1, and only one cross-connection arc 9b for each half-width solar cell 1 (the marginal solar cells).

The cross-connector 5 essentially covers the cross-connection arcs 9b. In the diagram according to FIG. 7, for clearer representation of the arrangement of the cross-connection arcs 9b, the cross-connection arcs 9b are also fully illustrated in the area covered by the cross-connector 5.

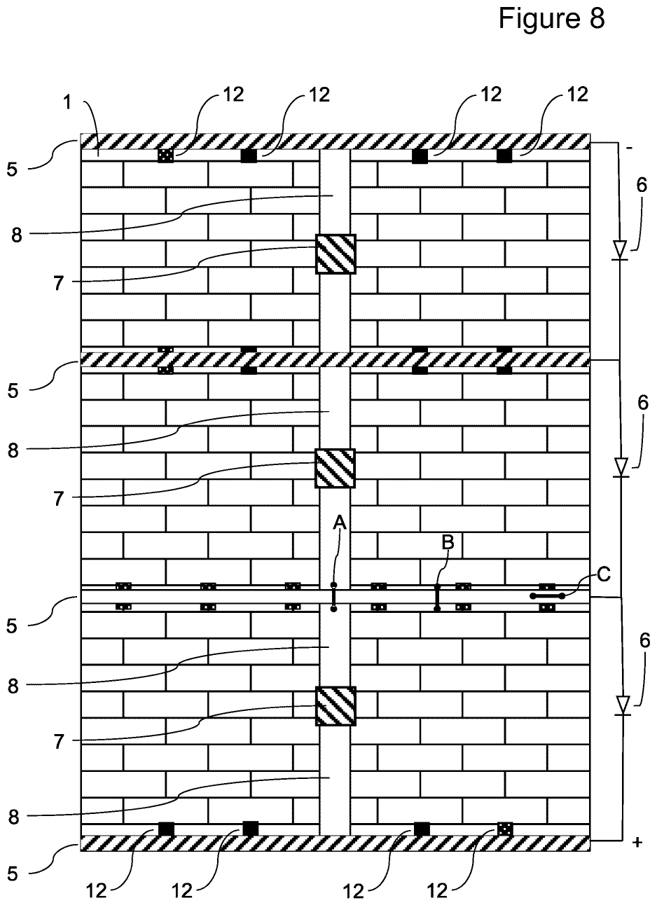

FIG. 8 shows a top view from behind of a fifth working example of a solar cell module of the invention. The structure corresponds in substantial parts to the structure of the solar cell module shown in FIG. 4. To avoid repetition, only the substantial differences are discussed below:

The solar cell module has 27 rows of solar cells, each with seven solar cells arranged next to one other. Four cross-connectors 5 are disposed on the backside of the solar cells. The cross-connectors 5 are electrically conductively connected by longitudinal connectors 8, with a connection socket 7 disposed in the middle between two cross-connectors 5, and with longitudinal connectors 8 leading thereto. In each case, a bypass diode is disposed in the connection socket 7, which connects the longitudinal connectors 8 that open into the connection socket 7. The interconnection with the bypass diodes 6 is shown schematically as an equivalent circuit diagram at the right-hand edge for clarity.

The solar cell module according to FIG. 8 thus has a total of four longitudinal connectors 8: The marginal cross-connectors 5 are each connected to the nearest connection socket 7 by a longitudinal connector 8. The middle connection socket 7 is connected to the upper and the lower connection sockets 7 via one longitudinal connector 8 each according to the diagram in FIG. 8.

In this diagram too, for better clarity, a solar cell is only marked top left with reference numeral 1.

The solar cell module shown in FIG. 8 has a plurality of cover strips 12 disposed between the solar cells 1 and the cross-connector 5 in the regions in which the cross-connectors 5 extend over the gap between two adjacent solar cells 1 in a row of solar cells. Therefore, from the frontside of the solar cell module, the cross-connectors 5 in the gaps between the solar cells are covered by the cover strips 12. The cover strips in the present case are black. In addition, the cover strips are designed to be electrically insulating in order to prevent unwanted current flows. For better representability, only the cover strips 12 on the upper and lower edges of the solar cell module are given reference numerals.

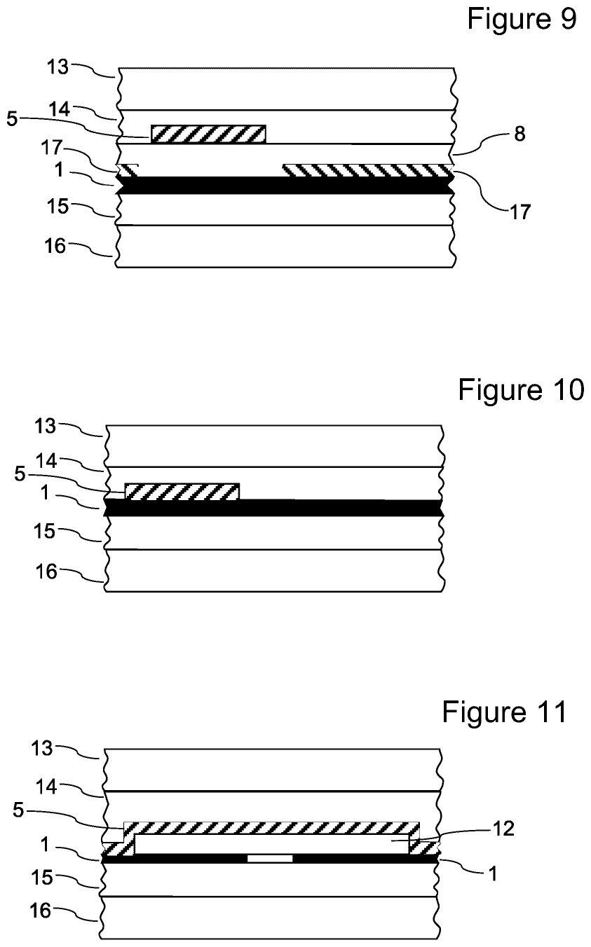

FIGS. 9 to 11 show cross-sectional diagrams of the solar cell module shown in FIG. 8. The section planes run in each case perpendicular to the plane of the drawing in FIG. 8. FIG. 9 shows a section along section line A in FIG. 8, FIG. 10 along section line B and FIG. 11 along section line C in FIG. 8. The section plane in FIG. 11 is thus perpendicular to the section planes of FIGS. 9 and 10.

FIG. 9 shows a section according to section line A in an area in which the cross-connector 5 crosses the longitudinal connector 8. The second cross-connector 5 starting from the bottom in FIG. 8 is therefore not shown with oblique stripes for a better overview.

As can be seen in FIG. 8, the cross-connectors 5 cover the longitudinal connectors 8 such that, in this overlap region, the longitudinal connectors 8 are disposed between the solar cells 1 and the cross-connectors 5.

As can be seen in FIG. 9, the solar cell module has the following layers proceeding from the backside:

a backside cover 13, about 400 μm (e.g. made of PE, PET);
a rear encapsulation film 14, about 400 μm (e.g. made of EVA, POE);
the solar cells 1 of the solar cell module about 180 μm (e.g. made of silicon);
a front encapsulation film 15, about 400 μm (e.g. made of EVA, POE), and a frontside glass 16, about 3.2 mm.

At the position of section A are additionally disposed a cross-connector 5 and a longitudinal connector 8, which cross at the position of section A.

In addition, a longitudinal connector insulation film 17 is arranged as insulating element between longitudinal connector 8 and solar cells 1, where the longitudinal connector insulation film 17 has a void at least in the region in which the cross-connector 5 covers the longitudinal connector 8. There is thus an electrically conductive connection between cross-connector 5, longitudinal connector 8 and the solar cells 1.

Cross-connector 5, longitudinal connector 8 and longitudinal connector insulation film 17 are thus arranged in that sequence between rear encapsulation film 14 and solar cells 1.

FIG. 8 does not show the full-area backside cover 13 and rear encapsulation film 14.

The section according to section line B in FIG. 10 shows a region in which the cross-connector 5 directly adjoins the solar cells 1.

A cover strip 12 is disposed at the position of section line C. The cover strip is disposed between the cross-connector 5 and the solar cells 1 such that, in plan view from the front, from the bottom in the diagram according to FIG. 11, in the gap between the solar cells 1, the cross-connector 5 is covered by the cover strip 12 so as to result in a visually uniform picture.

### LIST OF REFERENCE SIGNS

1 solar cell
2 contact fingers
3, 9a busbar
4 overlap region
5 cross-connector
6 bypass diode
7 connection socket
8 longitudinal connector
9 backside contacting structure
9b cross-connection arcs
10 series interconnection subregion
11 cross-connection subregion
12 cover strips
13 backside cover
14 rear encapsulation film
15 front encapsulation film
16 frontside glass
17 longitudinal connector insulation film

1. A solar cell module, comprising:
a plurality of photovoltaic solar cells with electrically contactable backsides;
wherein the solar cells are arranged in a matrix shingle arrangement having multiple rows of solar cells each having multiple ones of the solar cells and in a spatially parallel arrangement, the rows of solar cells are in an overlapping arrangement in overlap regions such that the backsides of the solar cells in one said row of solar cells partly cover front-sides of the solar cells in an adjacent one of the rows of solar cells;
the solar cells are arranged such that at least one of the backsides of one of the solar cells (1) in one said row of solar cells partly covers the front-sides of at least two of the solar cells in an adjacent one of the rows of solar cells; and
at least one of the rows of solar cells has an electrically conductive cross-connector (5) that covers at least 50% of and makes electrical contact with the backsides of each of at least non-marginal ones of the solar cells (1) of the row of solar cells.

2. The solar cell module as claimed in claim 1, wherein the cross-connector (5) covers at least 60%, of and makes electrical contact with the backsides of each of at least the non-marginal ones of the solar cells in the row of solar cells.

3. The solar cell module as claimed in claim 1, wherein the cross-connector (5) comprises an electrically conductive adhesive tape.

4. The solar cell module as claimed in claim 1, wherein the cross-connector (5) is in a mechanical and electrically conductive arrangement via a conductive adhesive on the solar cells.

5. The solar cell module as claimed in claim 1, further comprising an electrically conductive longitudinal connector (8) electrically conductively connected to the cross-connector (5) of one said row of solar cells, where the longitudinal connector (8) extends across further ones of the rows of solar cells and/or further cross-connectors (5) of the solar cell module, and the longitudinal connector (8) is electrically insulated from the further rows of solar cells and/or the further cross-connectors of the solar cell module by an electrically insulating layer of the solar cell module.

6. The solar cell module as claimed in claim 5, further comprising one connection socket (7) on each of at least two of the rows of solar cells and the longitudinal connector (8) extends between the connection sockets, and electrically conductively connects electrical connections of the two connection sockets.

7. The solar cell module as claimed in claim 1, wherein in that the cross-connector (5) is electrically conductively connected to a bypass diode (6).

8. The solar cell module as claimed in claim 1, wherein the cross-connector (5) is disposed on a terminal one of the rows of solar cells of the solar cell module and is electrically conductively connected to a connecting element for interconnection of the solar cell module to an external electrical element.

9. The solar cell module as claimed in claim 1, wherein the cross-connector (5) on a side facing the solar cells in the row of solar cells, at least in gaps between the solar cells, is blue or black over a whole area.

10. The solar cell module as claimed in claim 1, wherein the solar cells at least of the row of solar cells on which the cross-connector (5) is disposed each have a metallic backside contacting structure (9) which extends beyond an overlap region (4) on the backside of the solar cell (1) such that a series interconnection subregion (10) of the metallic backside contacting structure (9) in the overlap region (4) adjoins a front-side of an adjacent one of the solar cells (1), and a cross-connection subregion (11) of the metallic backside contacting structure (9) is covered by and directly electrically conductively connected to the cross-connector (5).

11. The solar cell module as claimed in claim 1, wherein, on the backside at least of the row of solar cells on which the cross-connector (5) is disposed, the solar cells each have a backside contacting surface formed from aluminum and the cross-connector (5) is disposed on the backside contacting surfaces and is directly electrically conductively connected to the backside contacting surfaces.

12. A method of producing a solar cell module, comprising the method steps of:
arranging multiple solar cells in a matrix shingle arrangement, so as to form multiple rows of solar cells each having multiple ones of the solar cells and in a spatially parallel arrangement, the rows of solar cells being in an overlapping arrangement in overlap regions such that backsides of the solar cells in one said row of solar cells partly cover front-sides of the solar cells in an adjacent one of the rows of solar cells;
arranging the solar cells such that at least one said backside of one of the solar cells (1) in one said row of solar cells partly covers the front-sides of at least two of the solar cells in an adjacent one of the rows of solar cells; and
disposing at least on one of the rows of solar cells an electrically conductive cross-connector (5) that covers at least 50% of and makes electrical contact with the backsides of each of at least non-marginal ones of the solar cells (1) of the row of solar cells.

13. The method as claimed in claim 12, wherein the cross-connector (5) is designed to cover and make electrical contact with at least 60% of the backsides of each of at least the non-marginal ones of the solar cells in the row of solar cells.

14. The method as claimed in claim 12, wherein the cross-connector (5) used is an electrically conductive adhesive tape.

15. The method as claimed in claim 12, further comprising disposing and electrically conductively connecting the cross-connector (5) to the row of solar cells by a conductive adhesive and curing the conductive adhesive during a lamination of the solar cell module.

16. The solar cell module as claimed in claim 1, wherein the solar cells at least of the row of solar cells on which the cross-connector (5) is disposed each have a metallic backside contacting structure which extends beyond an overlap region on the backside of the solar cell such that a series interconnection subregion of the metallic backside contacting structure in the overlap region adjoins the front-side of an adjacent one of the solar cells, and a cross-connection subregion of the metallic backside contacting structure is covered by and directly electrically conductively connected to the cross-connector (5).

17. The solar cell module as claimed in claim 1, wherein cross-connector (5) is mechanically connected to the solar cells over at least 80% of an area, with which the cross-connector (5) covers the backsides of solar cells in the row of solar cells.

18. The solar cell module as claimed in claim 5, wherein the longitudinal connector (8) is disposed between the solar cells and the cross-connector (5), and the longitudinal connector (8) is electrically conductively connected to the solar cells in a region in which the cross-connector (5) covers the longitudinal connector (8).

19. The solar cell module as claimed in claim 7, wherein there are at least two of the rows of solar cells each with the cross-connector (5) and the bypass diode (6) is electrically connected to the cross-connectors.
